(19) United States
(12) Patent Application Publication
(10) Pub. No.: US 2016/0356934 A1
(43) Pub. Date: Dec. 8, 2016

(54) CIRCULAR POLARIZER AND FABRICATING METHOD THEREOF, AS WELL AS DISPLAY PANEL

(71) Applicant: BOE TECHNOLOGY GROUP CO., LTD., Beijing (CN)

(72) Inventor: Wenbo Li, Beijing (CN)

(21) Appl. No.: 14/892,639

(22) PCT Filed: Jun. 9, 2015
(86) PCT No.: PCT/CN2015/081028

§ 371 Date: Nov. 20, 2015

(30) Foreign Application Priority Data
Dec. 30, 2014 (CN) 201410844297.X

(51) Int. Cl. G02B 5/30; B29D 11/00; G03F 7/20

(52) U.S. Cl. CPC G02B 5/3016; G02B 5/305; G02B 5/3083; G02B 5/3058; G03F 7/20; B29D 11/00644; B29D 11/00865

(57) ABSTRACT

The present invention relates to the technical field of polarizer, and discloses a circular polarizer and a fabricating method thereof, as well as a display panel. The circular polarizer comprises a substrate, as well as a linear grating structure layer and a quarter-wave plate which are located on one side of the substrate. In specific implementations, the quarter-wave plate is a quarter-wave plate formed from a photo-polymerized liquid crystal material. The above circular polarizer may be directly integrated on an upper substrate and/or a lower substrate of a display panel, thereby simplifying the structure of the display panel.

### TECHNICAL FIELD

The present invention relates to the technical field of polarizer, and particularly relates to a circular polarizer and a fabricating method thereof, as well as a display panel.

### BACKGROUND ART

In the prior art, when there is a need for obtaining circularly polarized light in a display panel, a circular polarizer is generally attached onto an upper substrate and/or lower substrate of the display panel, which makes the structure of the display panel to be more complex.

### SUMMARY OF THE INVENTION

The present invention provides a circular polarizer and a fabricating method thereof, as well as a display panel. The circular polarizer may be directly integrated on an upper substrate and/or a lower substrate of a display panel, thereby simplifying the structure of the display panel. To achieve the above objective, the present invention provides the following technical solution:

a circular polarizer, comprising a substrate, as well as a linear grating structure layer and a quarter-wave plate which are located on one side of the substrate. In specific implementations, the quarter-wave plate is a quarter-wave plate formed from a photo-polymerized liquid crystal material.

A light beam may become linearly polarized light after passing through a linear grating structure, and the linearly polarized light may become circularly polarized light after passing through a quarter-wave plate. Accordingly, the above circular polarizer may obtain circularly polarized light through a combination of the linear grating structure layer and the quarter-wave plate. Because the linear grating structure layer and the quarter-wave plate of the above circular polarizer are formed on the substrate, when the substrate of the above circular polarizer is the upper substrate and/or the lower substrate of the display panel, the linear grating structure layer and the quarter-wave plate of the above circular polarizer may be directly formed on the upper substrate and/or the lower substrate of the display panel. At this time, the above circular polarizer is integrated on the display panel, thus the structure of the display panel may be simplified.

In specific implementations, grating spacing of the linear grating structure layer is less than 200 nm.

In specific implementations, grating spacing of the linear grating structure layer is 60-100 nm.

In specific implementations, the quarter-wave plate is a wave plate which makes an optical path difference between o light and e light to be a quarter wavelength, or the quarter-wave plate is a wave plate which makes an optical path difference between o light and e light to be a three-quarter wavelength, or the quarter-wave plate is a wave plate formed by arranging wave plates which make an optical path difference between o light and e light to be a quarter wavelength as well as wave plates which make an optical path difference between o light and e light to be a three-quarter wavelength at intervals.

In specific implementations, the linear grating structure layer is located between the substrate and the quarter-wave plate.

In specific implementations, the quarter-wave plate is located between the substrate and the linear grating structure layer.

The present invention further provides a display panel, the display panel comprises an upper substrate and a lower substrate, wherein the upper substrate is the circular polarizer according to any one of the above technical solutions, and/or the lower substrate is the circular polarizer according to any one of the above technical solutions.

The present invention further provides a fabricating method for a circular polarizer, comprising:

cleaning a substrate; and

forming a linear grating structure layer and a quarter-wave plate on the substrate.

In specific implementations, the quarter-wave plate is a quarter-wave plate formed from a photo-polymerized liquid crystal material.

In specific implementations, the step of forming a linear grating structure layer and a quarter-wave plate on the substrate particularly comprises:

forming the linear grating structure layer on the substrate;

coating an over coating material on the linear grating structure layer and flattening; and

forming the quarter-wave plate on the over coating material.

As described above, the term “flattening” refers to a treatment to the over coating, such that it has a flat surface, thereby facilitating formation of further layers thereon.

In specific implementations, the step of forming the linear grating structure layer on the substrate particularly comprises: forming a metal layer on the substrate, and performing glue application, exposure and development on the metal layer, to form the linear grating structure;

The step of forming the quarter-wave plate on the over coating material particularly comprises: forming a photo-polymerized liquid crystal material on the over coating material, and irradiating the photo-polymerized liquid crystal material with ultraviolet polarized light, to form the quarter-wave plate.

In specific implementations, the exposure is exposure performed by an interference exposure with laser.

In specific implementations,

the step of forming the linear grating structure layer on the substrate particularly comprises: forming a metal layer on the substrate, coating an imprintable liquid material on the metal layer, imprinting the liquid material with a concave-convex nano-imprinting mold, as well as photo-curing and demolding, to form a cured material with a grating pattern; then, etching and developing the metal layer by using the cured material as a mask plate, to form the linear grating structure; and

the step of forming the quarter-wave plate on the over coating material particularly comprises: forming a photo-polymerized liquid crystal material on the over coating material, and irradiating the photo-polymerized liquid crystal material with ultraviolet polarized light, to form the quarter-wave plate.

In specific implementations, the step of forming the metal layer on the substrate particularly comprises: sputtering or evaporating the metal layer on the substrate.

In specific implementations, the step of forming a linear grating structure layer and a quarter-wave plate on the substrate particularly comprises:

forming the quarter-wave plate on the substrate;

forming a protective layer on the quarter-wave plate; and

forming the linear grating structure layer on the protective layer.

In specific implementations,

the step of forming the linear grating structure layer on the protective layer particularly comprises: forming a metal layer on the protective layer, and performing glue application, exposure and development on the metal layer, to form the linear grating structure; and

the step of forming the quarter-wave plate on the substrate particularly comprises: forming a photo-polymerized liquid crystal material on the substrate, and irradiating the photo-polymerized liquid crystal material with ultraviolet polarized light, to form the quarter-wave plate.

In specific implementations, the exposure is exposure performed by an interference exposure with laser.

In specific implementations,

the step of forming the linear grating structure layer on the protective layer particularly comprises: forming a metal layer on the protective layer, coating an imprintable liquid material on the metal layer, and imprinting the liquid material with a concave-convex nano-imprinting mold, as well as photo-curing and demolding, to form a cured material with a grating pattern; then, etching and developing the metal layer by using the cured material as a mask plate, to form the linear grating structure; and

the step of forming the quarter-wave plate on the substrate particularly comprises: forming a photo-polymerized liquid crystal material on the substrate, and irradiating the photo-polymerized liquid crystal material with ultraviolet polarized light, to form the quarter-wave plate.

In specific implementations, the step of forming the metal layer on the substrate particularly comprises: sputtering or evaporating the metal layer on the substrate.

### BRIEF DESCRIPTION OF THE DRAWINGS

FIG. 1a-1d are schematic views of a fabricating process for a circular polarizer provided by an embodiment of the present invention;

FIG. 2a-2f are schematic views of a fabricating process for another circular polarizer provided by an embodiment of the present invention;

FIG. 3a-3d are schematic views of a fabricating process for still another circular polarizer provided by an embodiment of the present invention;

FIG. 4a-4f are schematic views of a fabricating process for a further circular polarizer provided by an embodiment of the present invention;

FIG. 5 is a flow chart of a fabricating process for a circular polarizer provided by an embodiment of the present invention; FIG. 6 is a flow chart of a fabricating process shown in FIG. 1a-1d;

FIG. 7 is a flow chart of a fabricating process shown in FIG. 2a-2f;

FIG. 8 is a flow chart of a fabricating process shown in FIG. 3a-3d; and

FIG. 9 is a flow chart of a fabricating process shown in FIG. 4a-4f.

### DETAILED DESCRIPTION OF THE INVENTION

The technical solutions of the embodiments of the present invention will be described below in a clearly and fully understandable way in connection with the drawings in the embodiments of the present invention. It is obvious that the described embodiments are just a part but not all of the embodiments of the present invention. Based on the embodiments of the present invention, those ordinarily skilled in the art can obtain all other embodiments without any inventive work, which should be all within the protective scope of the present invention.

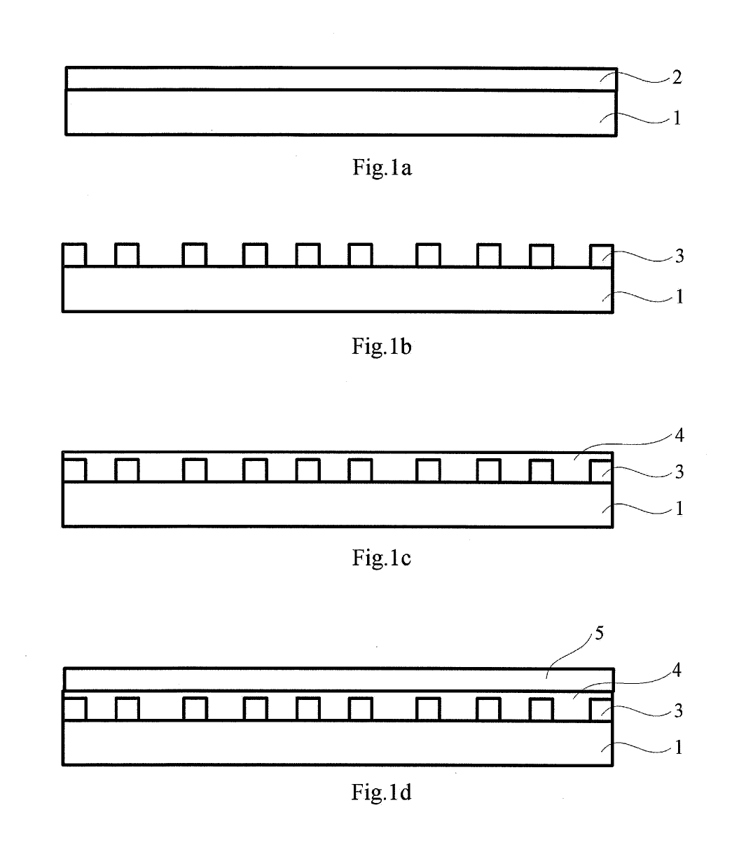

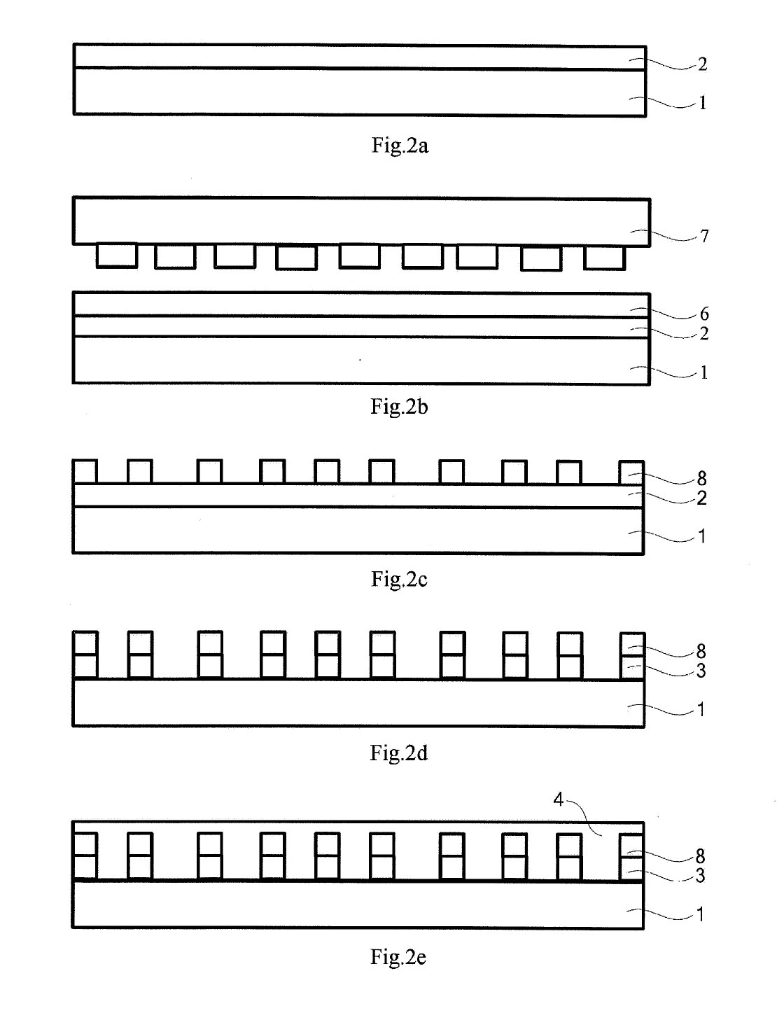

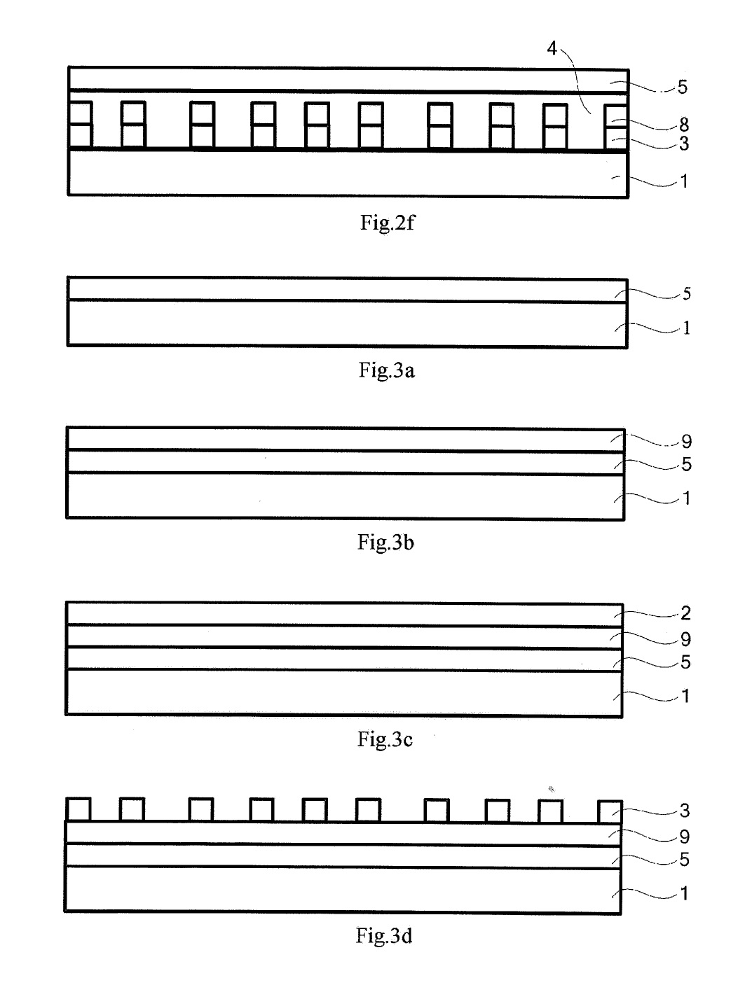

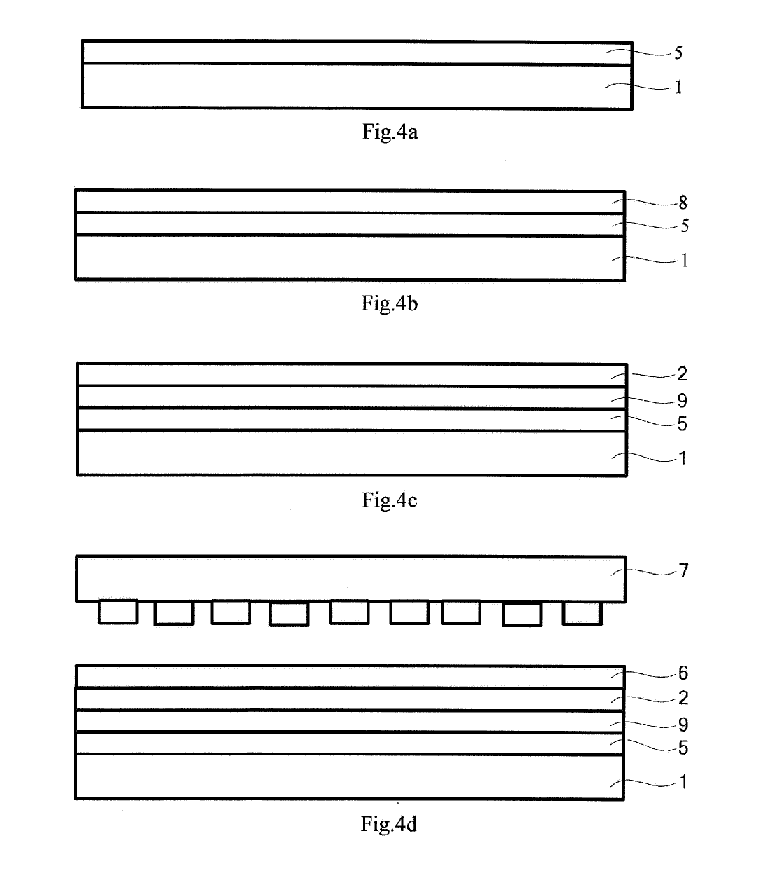

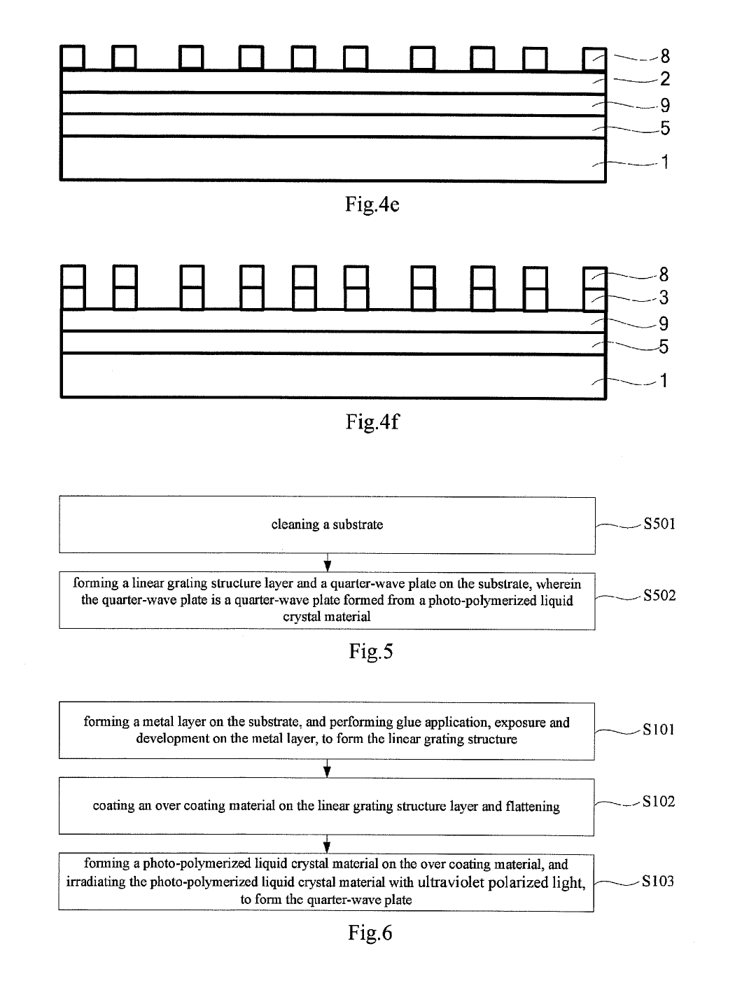

With reference to FIG. 1a-1d, FIG. 2a-2f, FIG. 3a-3d and FIG. 4a-4f, FIG. 1a-1d are schematic views of a fabricating process for a circular polarizer provided by an embodiment of the present invention; FIG. 2a-2f are schematic views of a fabricating process for another circular polarizer provided by an embodiment of the present invention; FIG. 3a-3d are schematic views of a fabricating process for still another circular polarizer provided by an embodiment of the present invention; and FIG. 4a-4f are schematic views of a fabricating process for a further circular polarizer provided by an embodiment of the present invention.

As shown in FIG. 1d, FIG. 2f, FIG. 3d and FIG. 4f, an embodiment of the present invention provides a circular polarizer, comprising a substrate 1, as well as a linear grating structure layer 3 and a quarter-wave plate 5 which are located on one side of the substrate 1. In specific implementations, the quarter-wave plate 5 is a quarter-wave plate 5 formed from a photo-polymerized liquid crystal display material.

A light beam may become linearly polarized light after passing through a linear grating structure, and the linearly polarized light may become circularly polarized light after passing through the quarter-wave plate. Accordingly, the above circular polarizer may obtain circularly polarized light through a combination of the linear grating structure layer 3 and the quarter-wave plate 5. Because the linear grating structure layer 3 and the quarter-wave plate 5 of the above circular polarizer are formed on the substrate 1, when the substrate 1 of the above circular polarizer is the upper substrate and/or the lower substrate of the display panel, the linear grating structure layer 3 and the quarter-wave plate 5 of the above circular polarizer may be directly formed on the upper substrate and/or the lower substrate of the display panel. At this time, the above circular polarizer is integrated on the display panel, thus the structure of the display panel may be simplified.

As shown in FIG. 1d, FIG. 2f, FIG. 3d and FIG. 4f, in a specific embodiment, grating spacing of the linear grating structure layer 3 is less than 200 nm. The grating spacing of the linear grating structure layer 3 needs to be less than one half of an incident light wavelength. Accordingly, when incident light is in a visible light waveband, the grating spacing of the linear grating structure layer 3 is less than 200 nm. In specific implementations, the grating spacing of the linear grating structure layer 3 may be 60-100 nm.

As shown in FIG. 1d, FIG. 2f, FIG. 3d and FIG. 4f, in a specific embodiment, the quarter-wave plate 5 may be in multiple forms:

a first form, the quarter-wave plate 5 is a wave plate which makes an optical path difference between o light and e light to be a quarter wavelength;

a second form, the quarter-wave plate 5 is a wave plate which makes an optical path difference between o light and e light to be a three-quarter wavelength; and

a third form, the quarter-wave plate 5 is a wave plate formed by arranging wave plates which make an optical path difference between o light and e light to be a quarter wavelength as well as wave plates which make an optical path difference between o light and e light to be a three-quarter wavelength at intervals.

On the basis of the above embodiments, in a specific embodiment, a position relation among the substrate 1, the linear grating structure layer 3 and the quarter-wave plate 5 may be as follows: as shown in FIG. 1d and FIG. 2f, the linear grating structure layer 3 is located between the substrate 1 and the quarter-wave plate 5; alternatively, as shown in FIG. 3d and FIG. 4f, the quarter-wave plate 5 is located between the substrate 1 and the linear grating structure layer 3.

An embodiment of the present invention further provides a display panel, the display panel comprises an upper substrate and a lower substrate, wherein the upper substrate is the circular polarizer according to any one of the above embodiments, and/or the lower substrate is the circular polarizer according to any one of the above embodiments. Accordingly, the circular polarizer is integrated in the above display panel, so that a circularly polarized light may be obtained, and the structure of the display panel is simple.

As shown in FIG. 5, an embodiment of the present invention further provides a fabricating method for a circular polarizer, comprising the following steps:

step S501, cleaning a substrate 1; and

step S502, forming a linear grating structure layer 3 and a quarter-wave plate 5 on the substrate 1.

In specific implementations, the quarter-wave plate 5 is a quarter-wave plate 5 formed from a photo-polymerized liquid crystal material.

When the substrate 1 is the upper substrate and/or the lower substrate of the display panel, the linear grating structure layer 3 and the quarter-wave plate 5 of the above circular polarizer may be directly formed on the upper substrate and/or the lower substrate of the display panel. That is, the above circular polarizer may be integrated in the display panel, thereby simplifying the structure of the display panel.

In a specific implementation, the step S502 of forming a linear grating structure layer 3 and a quarter-wave plate 5 on the substrate 1 may particularly comprise:

forming the linear grating structure layer 3 on the substrate 1;

coating an over coating material 4 on the linear grating structure layer 3 and flattening; and

forming the quarter-wave plate 5 on the over coating material 4.

Particularly, the above implementation may comprise the following embodiments:

A first specific embodiment, as shown in FIG. 1a-1d and FIG. 6,

step S101, as shown in FIG. 1a and FIG. 1b, forming a metal layer 2 on the substrate 1, and performing glue application, exposure and development on the metal layer 2, to form the linear grating structure;

step S102, as shown in FIG. 1c, coating an over coating material 4 on the linear grating structure layer 3 and flattening; and

step S103, as shown in FIG. 1d, forming a photo-polymerized liquid crystal material on the over coating material 4, and irradiating the photo-polymerized liquid crystal material with ultraviolet polarized light, to form the quarter-wave plate 5. The quarter-wave plate 5 is formed by orientating and curing with ultraviolet light of different polarization directions, thereby being realized without a mask plate.

In specific implementations, the above exposure process may be performed by an interference exposure with laser. That is, the exposure is performed by using interference fringes formed by laser with a particular wavelength through irradiating from two directions with an included angle of θ. By changing the included angle θ, linear grating structures with various spacing may be obtained within the used laser wavelength range.

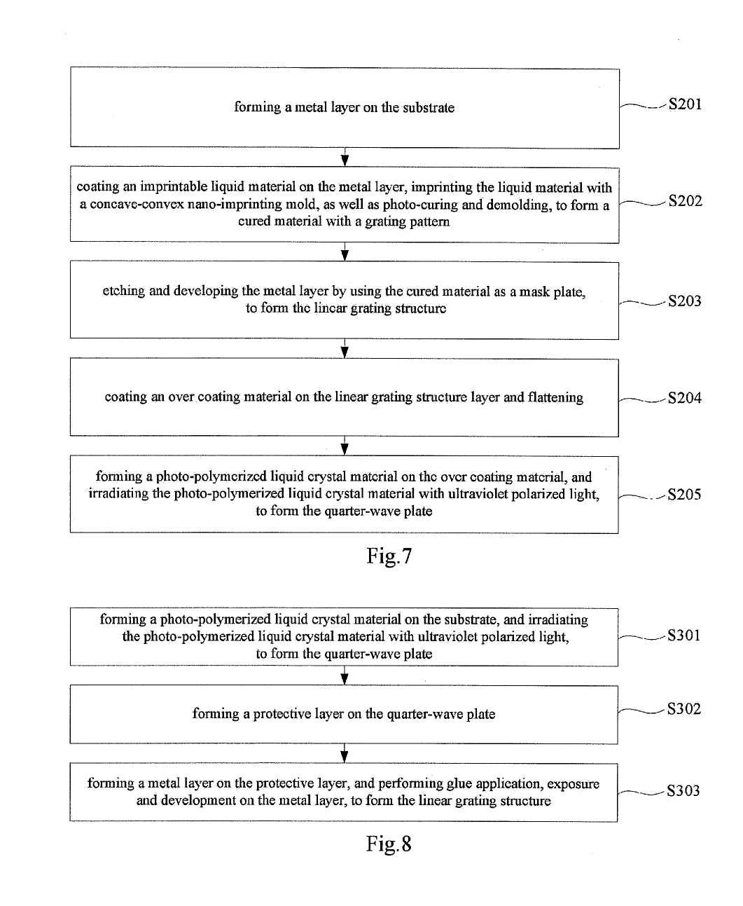

A second specific embodiment, as shown in FIG. 2a-2f and FIG. 7,

step S201, as shown in FIG. 2a, forming a metal layer 2 on the substrate 1;

step S202, as shown in FIG. 2b and FIG. 2c, coating an imprintable liquid material 6 on the metal layer 2, imprinting the liquid material 6 by using a concave-convex nano-imprinting mold 7, as well as photo-curing and demolding, to form a cured material 8 with a grating pattern;

step S203, as shown in FIG. 2d, etching and developing the metal layer 2 by using the cured material 8 as a mask plate, to form the linear grating structure;

step S204, as shown in FIG. 2e, coating an over coating material 4 on the linear grating structure layer 3 and flattening; and

step S205, as shown in FIG. 2f, forming a photo-polymerized liquid crystal material on the over coating material 4, and irradiating the photo-polymerized liquid crystal material with ultraviolet polarized light, to form the quarter-wave plate 5. The quarter-wave plate 5 is formed by orientating and curing with ultraviolet light of different polarization directions, thereby being realized without a mask plate.

In specific implementations, the metal layer 2 may be particularly formed on the substrate 1 by a sputtering or evaporating method.

In another specific implementation, the step S502 of forming a linear grating structure layer 3 and a quarter-wave plate 5 on the substrate 1 may particularly comprise:

forming the quarter-wave plate 5 on the substrate 1;

forming a protective layer 9 on the quarter-wave plate 5; and

forming the linear grating structure layer 3 on the protective layer 9.

Particularly, the above implementation may comprise the following embodiments:

A first specific embodiment, as shown in FIG. 3a-3d and FIG. 8,

step S301, as shown in FIG. 3a, forming a photo-polymerized liquid crystal material on the substrate 1, and irradiating the photo-polymerized liquid crystal material with ultraviolet polarized light, to form the quarter-wave plate 5. The quarter-wave plate 5 is formed by orientating and curing with ultraviolet light of different polarization directions, thereby being realized without a mask plate;

step S302, as shown FIG. 3d, forming a protective layer 9 on the quarter-wave plate 5; and

step S303, as shown in FIG. 3c and FIG. 3d, forming a metal layer 2 on the protective layer 9, and performing glue application, exposure and development on the metal layer 2, to form the linear grating structure.

In specific implementations, the exposure is exposure performed by an interference exposure with laser. That is, exposure is performed by using interference fringes formed by laser with a particular wavelength through irradiating from two directions with an included angle of θ. By changing the included angle θ, linear grating structures with various spacing may be obtained within the used laser wavelength range.

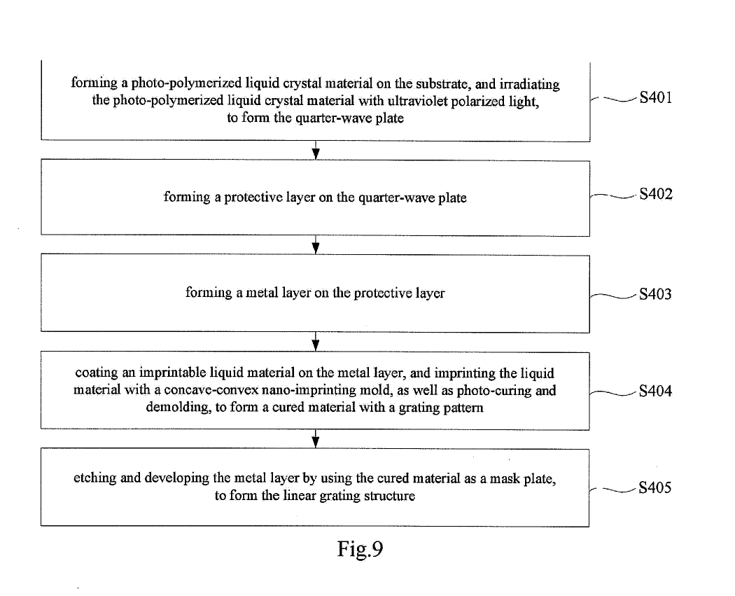

A second specific embodiment, as shown in FIG. 4a-4f and FIG. 9,

step S401, as shown in FIG. 4a, forming a photo-polymerized liquid crystal material on the substrate 1, and irradiating the photo-polymerized liquid crystal material with ultraviolet polarized light, to form the quarter-wave plate 5. The quarter-wave plate 5 is formed by orientating and curing with ultraviolet light of different polarization directions, thereby being realized without a mask plate;

step S402, as shown FIG. 4b, forming a protective layer 9 on the quarter-wave plate 5;

step S403, as shown in FIG. 4c, forming a metal layer 2 on the protective layer 9;

step S404, as shown in FIG. 4d and FIG. 4e, coating an imprintable liquid material 6 on the metal layer 2, and imprinting the liquid material 6 by using a concave-convex nano-imprinting mold 7, as well as photo-curing and demolding, to form a cured material 8 with a grating pattern; and

step S405, as shown in FIG. 4f, etching and developing the metal layer 5 by using the cured material 8 as a mask plate, to form the linear grating structure.

In specific implementations, the metal layer 2 may be particularly formed on the substrate 1 by a sputtering or evaporating method.

It will be apparent to those skilled in the art that various modifications and alterations can be made to the present invention without departing from the scope and spirit of the present invention. It is intended that the present invention covers these modifications and variations of the present invention provided they come within the scope of the appended claims and their equivalents.

1. A circular polarizer, comprising:
a substrate; and
a linear grating structure layer and a quarter-wave plate, which are located on one side of said substrate.

2. The circular polarizer according to claim 1, wherein said quarter-wave plate is a quarter-wave plate formed from a photo-polymerized liquid crystal material.

3. The circular polarizer according to claim 1, wherein grating spacing of said linear grating structure layer is less than 200 nm.

4. The circular polarizer according to claim 3, wherein grating spacing of said linear grating structure layer is 60-100 nm.

5. The circular polarizer according to claim 1, wherein said quarter-wave plate is a wave plate which makes an optical path difference between o light and e light to be a quarter wavelength, or said quarter-wave plate is a wave plate which makes an optical path difference between o light and e light to be a three-quarter wavelength, or said quarter-wave plate is a wave plate formed by arranging wave plates which make an optical path difference between o light and e light to be a quarter wavelength as well as wave plates which make an optical path difference between o light and e light to be a three-quarter wavelength at intervals.

6. The circular polarizer according to claim 1, wherein said linear grating structure layer is located between said substrate and said quarter-wave plate.

7. The circular polarizer according to claim 1, wherein said quarter-wave plate is located between said substrate and said linear grating structure layer.

8. A display panel, comprising an upper substrate and a lower substrate, wherein said upper substrate is the circular polarizer according to claim 1, and/or said lower substrate is the circular polarizer according to claim 1.

9. A fabricating method for a circular polarizer, comprising:
cleaning a substrate; and
forming a linear grating structure layer and a quarter-wave plate on said substrate.

10. The fabricating method according to claim 9, wherein said quarter-wave plate is a quarter-wave plate formed from a photo-polymerized liquid crystal material.

11. The fabricating method according to claim 9, wherein said forming a linear grating structure layer and a quarter-wave plate on said substrate comprises:
forming said linear grating structure layer on said substrate;
coating an over coating material on said linear grating structure layer and flattening; and
forming said quarter-wave plate on said over coating material.

12. The fabricating method according to claim 11, wherein
the step of forming said linear grating structure layer on said substrate comprises: forming a metal layer on said substrate, and performing glue application, exposure and development on said metal layer, to form said linear grating structure; and
the step of forming said quarter-wave plate on said over coating material comprises: forming a photo-polymerized liquid crystal material on said over coating material, and irradiating said photo-polymerized liquid crystal material with ultraviolet polarized light, to form said quarter-wave plate.

13. The fabricating method according to claim 12, wherein said exposure is exposure performed by an interference exposure with laser.

14. The fabricating method according to claim 11, wherein
the step of forming said linear grating structure layer on said substrate comprises: forming a metal layer on said substrate, coating an imprintable liquid material on said metal layer, imprinting said liquid material with a concave-convex nano-imprinting mold, photo-curing and demolding, to form a cured material with a grating pattern; etching and developing said metal layer by using said cured material as a mask plate, to form said linear grating structure; and
the step of forming said quarter-wave plate on said over coating material comprises: forming a photo-polymerized liquid crystal material on said over coating material, and irradiating said photo-polymerized liquid crystal material with ultraviolet polarized light, to form said quarter-wave plate.

15. The fabricating method according to claim 12, wherein the step of forming said metal layer on said substrate comprises: sputtering or evaporating said metal layer on said substrate.

16. The fabricating method according to claim 9, wherein the step of forming a linear grating structure layer and a quarter-wave plate on said substrate comprises:
forming said quarter-wave plate on said substrate;
forming a protective layer on said quarter-wave plate; and
forming said linear grating structure layer on said protective layer.

17. The fabricating method according to claim 16, wherein
the step of forming said linear grating structure layer on said protective layer comprises: forming a metal layer on said protective layer, and performing glue application, exposure and development on said metal layer, to form said linear grating structure; and
the step of forming said quarter-wave plate on said substrate comprises: forming a photo-polymerized liquid crystal material on said substrate, and irradiating said photo-polymerized liquid crystal material with ultraviolet polarized light, to form said quarter-wave plate.

18. The fabricating method according to claim 17, wherein said exposure is exposure performed by an interference exposure with laser.

19. The fabricating method according to claim 16, wherein
the step of forming said linear grating structure layer on said protective layer comprises: forming a metal layer on said protective layer, coating an imprintable liquid material on said metal layer, and imprinting said liquid material with a concave-convex nano-imprinting mold, photo-curing and demolding, to form a cured material with a grating pattern; etching and developing said metal layer by using said cured material as a mask plate, to form said linear grating structure; and
the step of forming said quarter-wave plate on said substrate comprises: forming a photo-polymerized liquid crystal material on said substrate, and irradiating said photo-polymerized liquid crystal material with ultraviolet polarized light, to form said quarter-wave plate.

20. The fabricating method according to of claim 17, wherein the step of forming said metal layer on said substrate comprises: sputtering or evaporating said metal layer on said substrate.
